(19) United States
(12) Patent Application Publication
(10) Pub. No.: US 2013/0195333 A1
(43) Pub. Date: Aug. 1, 2013

(54) Method for Forming a Graded Matching Layer Structure

(71) Applicants: Prabhjot Singh, Guilderland, NY (US); Lowell Scott Smith, Niskayuna, NY (US)

(72) Inventors: Prabhjot Singh, Guilderland, NY (US); Lowell Scott Smith, Niskayuna, NY (US)

(73) Assignee: GENERAL ELECTRIC COMPANY, SCHENECTADY, NY (US)

(21) Appl. No.: 13/362,096

(22) Filed: Jan. 31, 2012

(51) Int. Cl. G06K 9/00; G10K 11/00; B05D 5/12; H01L 41/04

(52) U.S. Cl. 382/131; 310/334; 181/175; 427/100

(57) ABSTRACT

A method for forming a graded matching layer structure is presented. The method includes (a) depositing a first material slurry on at least a portion of a substrate, (b) spreading the first material slurry to a form a first material layer having a first determined thickness, (c) exposing the first material layer using light processed through a determined light pattern mask to form a first matching layer, and (d) repeating steps (a)-(c) with different material slurries to form the graded matching layer structure.

### STATEMENT OF FEDERALLY FUNDED RESEARCH

This invention was made with Government support under grant number 1RC2EB011439-01 awarded by the National Institutes of Health. The Government has certain rights in the invention.

### BACKGROUND

Embodiments of the present disclosure relate to imaging, and more particularly to patterning a graded matching layer structure for use in ultrasound transducers.

Sensors or transducers are devices that transform input signals of one form into output signals of a different form. Commonly used transducers include light sensors, heat sensors, and acoustic sensors. An example of an acoustic sensor is an ultrasonic transducer. In ultrasound devices, the transducers transform signals of electrical energy into acoustic energy or produce electrical signals from absorbed sound waves. Various applications, such as biomedical non-invasive diagnostics and non-destructive testing (NDT) of materials entail the use of sensors. Applications such as medical and industrial imaging, non-destructive testing (NDT), security, baggage scanning, astrophysics and medicine may also entail the use of sensors.

Moreover, ultrasound transducers used for medical imaging and/or non-destructive testing are generally characterized by properties such as sensitivity and bandwidth, which are directly correlated to the penetration and resolution of the imaging system. In recent years, the fractional bandwidth of the ultrasound transducers has dramatically increased. As will be appreciated, the fractional bandwidth is defined as the bandwidth divided by the center frequency. Use of an ultrasound probe having a transducer assembly with a broad fractional bandwidth greatly enhances quality of imaging, resolution of the imaging system, and clinical workflow.

A typical probe, such as an ultrasound probe, includes a transducer assembly or package, a multi-wire cable connecting the transducer to the rest of an imaging system, such as an ultrasound system, and other miscellaneous mechanical hardware such as the probe housing, thermal and/or acoustic potting material and electrical shielding. Moreover, the transducer assembly includes a structure having an acoustic layer having plurality of transducer elements that are sandwiched between one or more matching layers on one side and a backing layer structure on the other side. The backing layer provides a structural function and/or an acoustic function, while the matching layers aid in bridging any gap in impedance between an object of interest and the transducer elements.

Acoustic transducer assemblies that include more than one matching layers have been employed to address the issue of impedance differential. Ideally it is desirable to have a matching layer structure that provides a gradient of impedance across its thickness from a low acoustic impedance of the object of interest to a high acoustic impedance of the transducer elements. Such a matching layer structure may be configured to enhance the fractional bandwidth of the transducer assembly. This matching layer structure leads to greater resolution of the imaging system and/or deeper penetration of the beam energy.

Graded matching layers having a plurality of matching layers have been proposed as a solution to the problem of impedance differential between the transducer assembly and the object been observed/diagnosed. However, increasing the number of matching layers especially when the matching layers are quarter wave sections in these graded matching layer configurations increases the thickness of the acoustic stack and also enhances attenuation of the signal. However, the manufacture of such a matching layer structure can be a challenge.

Certain currently available methods entail fabrication of such graded matching structures either using several layers of homogeneous materials that are subsequently diced, or geometrically shaped structures from a homogeneous material. Moreover these complex structures tend to be difficult and expensive to manufacture. The dicing operation is difficult due to the thicker layers and requires a high amount of blade exposure.

Moreover, certain other methods vary the acoustic impedance using a taper to maximize bandwidth. In other techniques, the acoustic impedance is varied by loading epoxies with material, while other methods control the impedance by controlling the volume fraction of material. Other techniques entail forming the matching layers using techniques including tapered structures, controlled porosity and different material combinations. In addition, some methods entail controlling the impedance by producing a matching layer with lead zirconate titanate (PZT) having continuously varying porosity, where the porosity is created by adding polymer beads which vaporize during sintering leaving behind voids. PZT aerogels have also been used to make a porous structure with controlled porosity and the acoustic impedance is varied by controlling pore sizes. Also, porous inorganic oxide structures created from gels having additives to occupy pores have been used to change the impedance.

Furthermore, some techniques call for deposition of matching layers by electroplating and then cutting grooves via photoetching, where the grooves are backfilled with epoxy. Other solutions such as a two matching layer solution have been pursued in which a first layer is made of a porous material with a filler and a second layer composed of only the filler material, while certain other techniques use deposition of material directly on to transducers using thick film deposition, followed by photolithographic techniques. Multi-layer structures have also been created by repeated deposition of materials. Also, the impedance is controlled by controlling a volume fraction of posts in a given impedance layer.

Disadvantageously, many previous attempts to bridge the impedance differential between the transducer assembly and the object being inspected/diagnosed have had limited effect on imaging performance of the transducer assembly. Additionally, these methods may be tedious and/or expensive. Also, the complex structures tend to be difficult and expensive to manufacture.

### BRIEF DESCRIPTION

In accordance with aspects of the present technique, a method for forming a graded matching layer structure is presented. The method includes (a) depositing a first material slurry on at least a portion of a substrate, (b) spreading the first material slurry to a form a first material layer having a first determined thickness, (c) exposing the first material layer using light processed through a determined light pattern mask to form a first matching layer, and (d) repeating steps (a)-(c) with different material slurries to form the graded matching layer structure.

In accordance with another aspect of the present technique, a graded matching layer structure is presented. The graded matching layer structure includes a plurality of matching layers arranged in a stacked structure, wherein each matching layer in the stacked structure has a different acoustic impedance, and wherein the stacked structure is configured to provide a stepwise monotonic change in acoustic impedance across the stacked structure.

In accordance with yet another aspect of the present technique, a transducer assembly is presented. The transducer array includes one or more transducer elements disposed in determined pattern. In addition, the transducer array includes a graded matching layer structure operatively coupled to the transducer array and comprising a plurality of matching layers arranged in a stacked structure, wherein each matching layer in the stacked structure has a different acoustic impedance, and wherein the stacked structure is configured to provide a stepwise monotonic change in acoustic impedance across the stacked structure.

In accordance with another aspect of the present technique, a system is presented. The system includes an acquisition subsystem configured to acquire image data, wherein the acquisition subsystem comprises a probe configured to image a region of interest, wherein the probe comprises at least one transducer assembly, wherein the at least one transducer assembly comprises a graded matching layer structure and a transducer array, wherein the graded matching layer structure comprises a plurality of matching layers arranged in a stacked structure, wherein each matching layer in the stacked structure has a different acoustic impedance, and wherein the stacked structure is configured to provide a stepwise monotonic change in acoustic impedance across the stacked structure. Moreover, the system includes a processing subsystem in operative association with the acquisition subsystem and configured to process the image data acquired via the acquisition subsystem.

### DRAWINGS

These and other features, aspects, and advantages of the present disclosure will become better understood when the following detailed description is read with reference to the accompanying drawings in which like characters represent like parts throughout the drawings, wherein:

FIG. 1 is a diagrammatical illustration of an imaging system configured to use an exemplary graded matching layer structure, in accordance with aspects of the present technique;

FIG. 2 is a block diagram illustration of an exemplary medical imaging system in the form of an ultrasound imaging system configured to use the exemplary graded matching layer structure and for use in the imaging system of FIG. 1;

FIG. 3 is a cross-sectional side view of an exemplary matching layer structure, in accordance with aspects of the present technique;

FIG. 4 is a flow chart depicting an exemplary method for forming the graded matching layer structure of FIG. 3, in accordance with aspects of the present technique;

FIG. 5 is a diagrammatical illustration of one exemplary method for forming the graded matching layer structure of FIG. 4, in accordance with aspects of the present technique;

FIG. 6 is a diagrammatical illustration of one exemplary method for forming the graded matching layer structure of FIG. 4, in accordance with aspects of the present technique;

FIG. 7 is a diagrammatical illustration of a transducer assembly configured to use the exemplary graded matching layer structure of FIG. 3, in accordance with aspects of the present technique; and

FIG. 8 is a diagrammatical illustration of a method of use of the transducer assembly of FIG. 7, in accordance with aspects of the present technique.

### DETAILED DESCRIPTION

As will be described in detail hereinafter, embodiments of a graded matching layer structure and methods for forming the graded matching layer structure are presented. The methods and systems described hereinafter provide a robust graded matching layer structure that advantageously enhances the sensitivity of the ultrasound transducer, and enhances the imaging resolution.

Although, the exemplary embodiments illustrated hereinafter are described in the context of a graded matching layer structure configured for use in a medical imaging system such as an ultrasound imaging system, it will be appreciated that use of the graded matching layer structure in an ultrasound imaging system in other applications such as equipment diagnostics and inspections, baggage inspections, security applications is also envisaged.

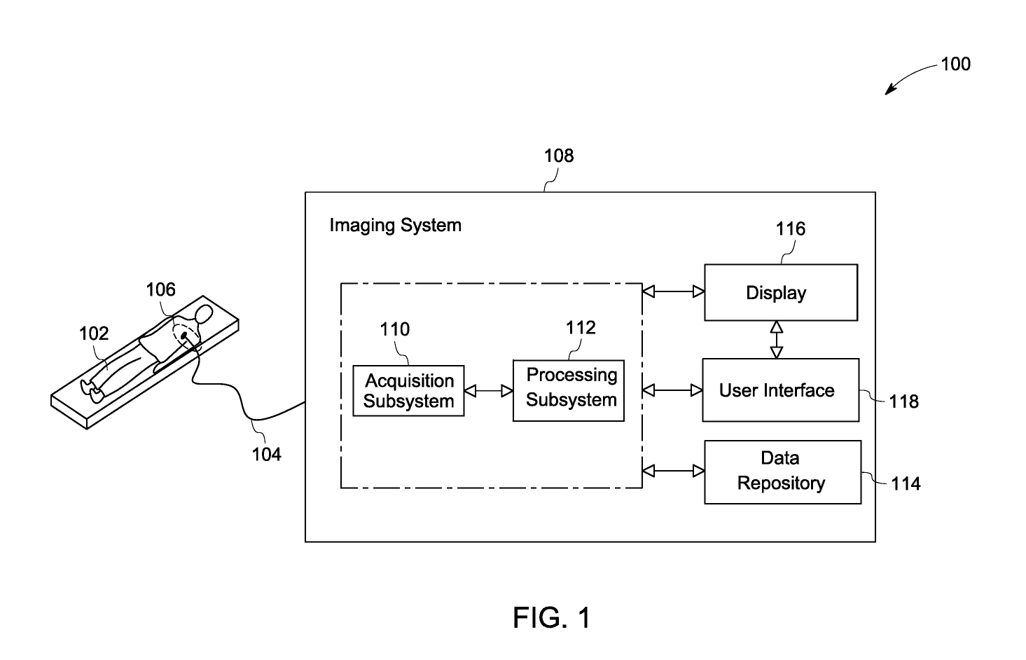

FIG. 1 is a block diagram of an exemplary system 100 for use in imaging, in accordance with aspects of the present technique. The system 100 may be configured to facilitate acquisition of image data from an object of interest via a probe 104, for example. In the present example of FIG. 1, the object of interest includes a patient 102. However, in certain other embodiments, the object of interest may include luggage, a sample, other equipment, and the like. For example, the probe 104 may be configured to acquire image data representative of a region of interest in the patient 102. In some embodiments, the probe 104 may be configured to facilitate interventional procedures. Accordingly, the probe 104 may include an invasive probe. However, in certain other embodiments, the probe 104 may include a non-invasive probe. It should also be noted that, although the embodiments illustrated are described in the context of a transthoracic probe, other types of probes such as endoscopes, laparoscopes, catheter-based probes, surgical probes, transrectal probes, transvaginal probes, intracavity probes, probes adapted for interventional procedures, other external probes or combinations thereof are also contemplated in conjunction with the present technique. Reference numeral 106 is representative of a portion of the probe 104 that is in contact with the patient 102.

In certain embodiments, the probe 104 may include an imaging catheter-based probe. Further, an imaging orientation of the imaging catheter 104 may include a forward viewing catheter, a side viewing catheter, or an oblique viewing catheter. However, a combination of forward viewing, side viewing and oblique viewing catheters may also be employed as the imaging catheter 104. The imaging catheter 104 may include an imaging transducer assembly (not shown in FIG. 1).

As will be appreciated, a transducer assembly typically includes an acoustic layer, where the acoustic layer may be configured to generate and transmit acoustic energy into the patient 102 (see FIG. 1) and receive backscattered acoustic signals from the patient 102 to create and display an image. In addition, the acoustic layer may include a plurality of transducer elements. Furthermore, a conventional transducer assembly may also include at least one matching layer disposed adjacent to the acoustic layer, an interconnect layer, a lens, and/or a backing layer. Additionally, the transducer assembly may include an interconnect layer that may be configured to operatively couple the acoustic layer of the transducer assembly to a cable assembly (not shown) or electronics (not shown in FIG. 1). The transducer assembly may include a highly attenuative backing layer. As will be appreciated, the low impedance backing layer in a conventional transducer assembly may be configured to serve a structural function and/or an acoustic function. Moreover, the lens may be disposed adjacent to a matching layer front face and configured to provide an interface between the patient and the matching layer. Additionally, in certain embodiments, the lens may be configured to facilitate focusing of the ultrasound beam. Alternatively, the lens may include a non-focusing layer.

As will be appreciated, the matching layer may be configured to facilitate matching of an impedance differential that may exist between the high impedance transducer elements in the acoustic layer and the low impedance patient 102. It may be noted that the transducer assembly may include more than one matching layer. As previously noted, the traditional matching layers fail to effectively match the impedance differential between the high impedance transducer elements and the object of interest, such as the patient 102.

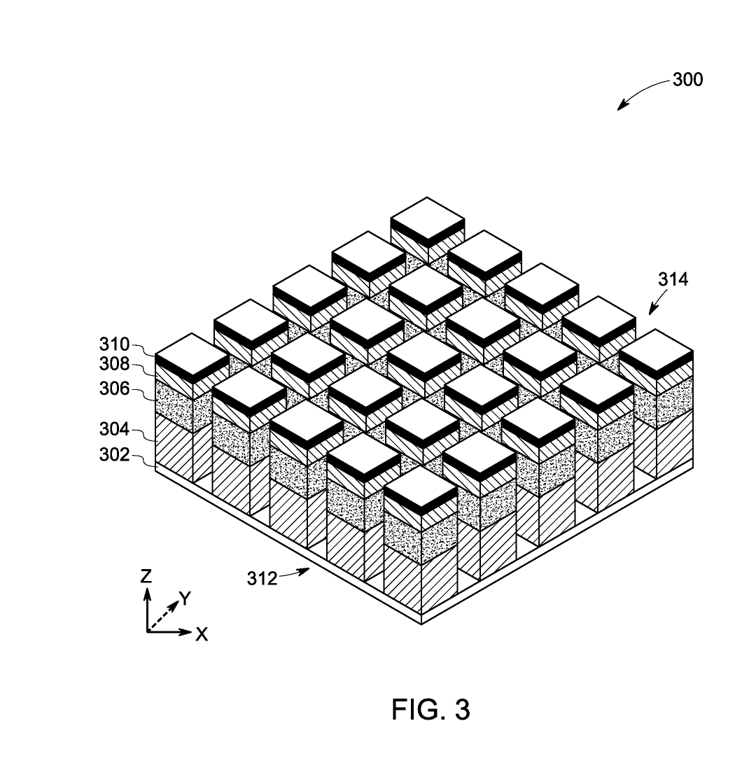

In accordance with aspects of the present technique, an exemplary graded matching layer structure is presented that may be configured to effectively bridge the impedance differential between the high impedance transducer elements and the object of interest, such as the patient 102. Also, the graded matching layer structure may be formed using an exemplary method. The graded matching layer structure and the method for forming the graded matching layer structure will be described in greater detail with reference to FIGS. 3-8.

The system 100 may also include an imaging system 108 that is in operative association with the imaging probe 104 and configured to facilitate acquisition and/or processing of image data. To that end, the imaging system 108 may include an acquisition subsystem 110 and a processing subsystem 112. The image data acquired and/or processed by the medical imaging system 108 may be employed to aid a clinician in identifying disease states, assessing need for treatment, determining suitable treatment options, tracking the progression of the disease, and/or monitoring the effect of treatment on the disease states. In certain embodiments, the processing subsystem 112 may be further coupled to a storage system, such as the data repository 114, where the data repository 114 is configured to store the acquired image data.

It should be noted that although the exemplary embodiments illustrated hereinafter are described in the context of a medical imaging system, such as an ultrasound imaging system, other imaging systems and applications such as industrial imaging systems and non-destructive evaluation and inspection systems, such as pipeline inspection systems, liquid reactor inspection systems are also contemplated. Additionally, the exemplary embodiments illustrated and described hereinafter may find application in multi-modality imaging systems that employ ultrasound imaging in conjunction with other imaging modalities, position-tracking systems or other sensor systems. Although, the exemplary embodiments illustrated hereinafter are described in the context of a medical imaging system, it will be appreciated that use of the probe with improved image quality and contrast resolution in industrial applications is also contemplated in conjunction with the present technique. For example, the exemplary embodiments illustrated and described hereinafter may find application in industrial borescopes that are employed for thickness monitoring, interface monitoring, or crack detection.

Further, the imaging system 108 may be configured to display the acquired image data. As illustrated in FIG. 1, the imaging system 108 may include a display area 116 and a user interface area 118. In accordance with aspects of the present technique, the display area 116 of the imaging system 108 may be configured to display the image generated by the imaging system 108 based on the image data acquired via the imaging probe 104. Additionally, the display area 116 may be configured to aid the user in visualizing the generated image. In certain embodiments, such as in a touch screen, the display 116 and the user interface 118 may overlap. Also, in some embodiments, the display 116 and the user interface 118 may include a common area. In accordance with aspects of the present technique, the display 116 of the medical imaging system 108 may be configured to display an image generated by the medical imaging system 108 based on the acquired image data.

In addition, the user interface 118 of the medical imaging system 108 may include a human interface device (not shown) configured to aid the clinician in manipulating image data displayed on the display 116. The human interface device may include a mouse-type device, a trackball, a joystick, a stylus, or a touch screen configured to facilitate the clinician to identify the one or more regions of interest requiring therapy. However, as will be appreciated, other human interface devices, such as, but not limited to, a touch screen, may also be employed. Furthermore, in accordance with aspects of the present technique, the user interface 118 may be configured to aid the clinician in navigating through the images acquired by the medical imaging system 108. Additionally, the user interface 118 may also be configured to aid in manipulating and/or organizing the acquired image data displayed on the display 116.

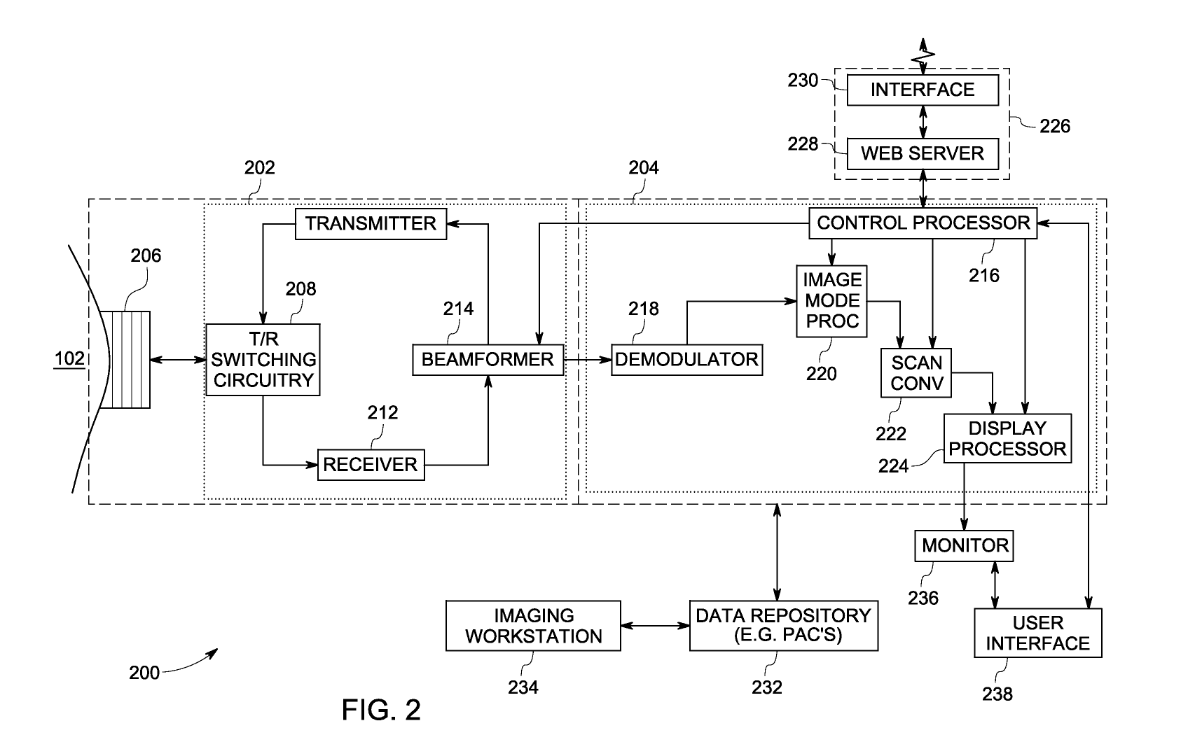

As previously noted with reference to FIG. 1, the medical imaging system 108 may include an ultrasound imaging system. Referring now to FIG. 2, a block diagram of an embodiment of an ultrasound imaging system 200 for use in the system 100 of FIG. 1 is depicted. The ultrasound system 200 includes an acquisition subsystem 202, such as the acquisition subsystem 110 of FIG. 1 and a processing subsystem 204, such as the processing subsystem 112 of FIG. 1. The acquisition subsystem 202 may include a transducer assembly 206. In accordance with aspects of the present technique, the transducer assembly 206 may include an exemplary graded matching layer structure (see FIG. 3) to enhance the resolution and sensitivity of the imaging system 200.

In addition, the acquisition subsystem 202 includes transmit/receive switching circuitry 208, a transmitter 210, a receiver 212, and a beamformer 214. It may be noted that in a presently contemplated configuration, the transducer assembly 206 is disposed in the probe 104 (see FIG. 1). Also, in certain embodiments, the transducer assembly 206 may include a plurality of transducer elements (not shown in FIG. 1) arranged in a spaced relationship to form a transducer array, such as a one-dimensional or two-dimensional transducer array, for example. Additionally, the transducer assembly 206 may include an interconnect structure (not shown in FIG. 1) configured to facilitate operatively coupling the transducer array to an external device (not shown in FIG. 1), such as, but not limited to, a cable assembly or associated electronics.

The processing subsystem 204 includes a control processor 216, a demodulator 218, an imaging mode processor 220, a scan converter 222 and a display processor 224. The display processor 224 is further coupled to a display monitor 236, such as the display area 116 (see FIG. 1), for displaying images. User interface 238, such as the user interface area 118 (see FIG. 1), interacts with the control processor 216 and the display monitor 236. The control processor 216 may also be coupled to a remote connectivity subsystem 226 including a web server 228 and a remote connectivity interface 230. The processing subsystem 204 may be further coupled to a data repository 232, such as the data repository 114 (see FIG. 1) configured to receive ultrasound image data. The data repository 232 interacts with an imaging workstation 234.

The aforementioned components may be dedicated hardware elements such as circuit boards with digital signal processors or may be software running on a general-purpose computer or processor such as a commercial, off-the-shelf personal computer (PC). The various components may be combined or separated according to various embodiments of the invention. Thus, those skilled in the art will appreciate that the present ultrasound imaging system 200 is provided by way of example, and the present techniques are in no way limited by the specific system configuration.

In the acquisition subsystem 202, the transducer assembly 206 is in contact with the patient 102 (see FIG. 1). The transducer assembly 206 is coupled to the transmit/receive (T/R) switching circuitry 208. Also, the T/R switching circuitry 208 is in operative association with an output of transmitter 210 and an input of the receiver 212. The output of the receiver 212 is an input to the beamformer 214. In addition, the beamformer 214 is further coupled to the input of the transmitter 210 and to the input of the demodulator 218. The beamformer 214 is also operatively coupled to the control processor 216 as shown in FIG. 2.

In the processing subsystem 204, the output of demodulator 218 is in operative association with an input of the imaging mode processor 220. Additionally, the control processor 216 interfaces with the imaging mode processor 220, the scan converter 222 and the display processor 224. An output of the imaging mode processor 220 is coupled to an input of scan converter 222. Also, an output of the scan converter 222 is operatively coupled to an input of the display processor 224. The output of display processor 224 is coupled to the monitor 236.

The ultrasound system 200 transmits ultrasound energy into the patient 102 and receives and processes backscattered ultrasound signals from the patient 102 to create and display an image. To generate a transmitted beam of ultrasound energy, the control processor 216 communicates command data to the beamformer 214 to generate transmit parameters to create a beam of a desired shape originating from a certain point at the surface of the transducer assembly 206 at a desired steering angle. The transmit parameters are communicated from the beamformer 214 to the transmitter 210. The transmitter 210 uses the transmit parameters to properly encode transmit signals to be sent to the transducer assembly 206 through the T/R switching circuitry 208. The transmit signals are set at certain amplitudes and phases with respect to each other and are provided to individual transducer elements of the transducer assembly 206. The transmit signals excite the transducer elements to emit ultrasound waves with the same phase and amplitudes relationships. As a result, a transmitted beam of ultrasound energy is formed in the patient 102 along a scan line when the transducer assembly 206 is acoustically coupled to the patient 102 by using, for example, ultrasound gel. The process of sequentially transmitting beams to different spatial locations is known as electronic scanning.

In one embodiment, the transducer assembly 206 may be a two-way transducer. When ultrasound waves are transmitted into a patient 102, the ultrasound waves are backscattered off the tissue and blood within the patient 102. The transducer assembly 206 receives the backscattered waves at different times, depending on the distance into the tissue they return from and the angle with respect to the surface of the transducer assembly 206 at which they return. The transducer elements convert the ultrasound energy from the backscattered waves into electrical signals.

The electrical signals are then routed through the T/R switching circuitry 208 to the receiver 212. The receiver 212 amplifies and digitizes the received signals and provides other functions such as gain compensation. The digitized received signals corresponding to the backscattered waves received by each transducer element at various times preserve the amplitude and phase information of the backscattered waves.

The digitized signals are communicated to the beamformer 214. The control processor 216 communicates command data to beamformer 214. The beamformer 214 uses the command data to form a receive beam originating from a point on the surface of the transducer assembly 206 at a steering angle typically corresponding to the point and steering angle of the previous ultrasound beam transmitted along a scan line. The beamformer 214 operates on the appropriate received signals by performing time delaying and focusing, according to the instructions of the command data from the control processor 216, to create received beam signals corresponding to sample volumes along a scan line within the patient 102. Additionally, in certain other embodiments, synthetic aperture beamforming techniques may also be employed. The phase, amplitude, and timing information of the received signals from the various transducer elements are used to create the received beam signals.

The received beam signals are communicated to the processing subsystem 204. The demodulator 218 demodulates the received beam signals to create pairs of I and Q demodulated data values corresponding to sample volumes along the scan line. Demodulation is accomplished by comparing the phase and amplitude of the received beam signals to a reference frequency. The I and Q demodulated data values preserve the phase and amplitude information of the received signals.

The demodulated data is transferred to the imaging mode processor 220. The imaging mode processor 220 uses parameter estimation techniques to generate imaging parameter values from the demodulated data in scan sequence format. The imaging parameters may include parameters corresponding to various possible imaging modes such as B-mode, color velocity mode, spectral Doppler mode, and tissue velocity imaging mode, for example. The imaging parameter values are passed to the scan converter 222. The scan converter 222 processes the parameter data by performing a translation from scan sequence format to display format. The translation includes performing interpolation operations on the parameter data to create display pixel data in the display format.

The scan converted pixel data is communicated to the display processor 224 to perform any final spatial or temporal filtering of the scan converted pixel data, to apply grayscale or color to the scan converted pixel data, and to convert the digital pixel data to analog data for display on the monitor 236. The user interface 238 is coupled to the control processor 216 to allow a user to interface with the ultrasound system 200 based on the data displayed on the monitor 236.

As previously noted, typically, a transducer assembly includes an acoustic layer having one or more transducer elements. The transducer elements may be arranged in a spaced relationship, such as, but not limited to, an array of transducer elements disposed on a layer, where each of the transducer elements may include a transducer front face and a transducer rear face. As will be appreciated by one skilled in the art, the transducer elements may be fabricated employing piezoelectric or micromachined electro-mechanical (MEMS) materials, such as, but not limited to lead zirconate titanate (PZT), lead magnesium niobate lead titanate (PMNT), composite PZT, or micromachined silicon. The transducer assembly may also include one or more matching layers disposed adjacent to the front face of the array of transducer elements, where each of the matching layers may include a matching layer front face and a matching layer rear face. The matching layers facilitate matching of an impedance differential that may exist between the high impedance transducer elements and a low impedance patient or subject 102 (see FIG. 1).

Moreover, in the conventional transducer assemblies, the one or more matching layers typically include homogeneous materials that are subsequently diced. Alternatively, the one or more matching layers may be geometrically shaped structures from a homogeneous material. However, these complex structures tend to be difficult and expensive to manufacture.

In accordance with aspects of the present technique, an exemplary graded matching layer structure that circumvents the shortcomings of the currently available matching layers is presented. In particular, the exemplary graded matching layer structure improves the penetration or sensitivity and resolution of an ultrasound transducer.

Turning now to FIG. 3, a cross-sectional side view of an exemplary graded matching layer structure 300 for use in the system 100 depicted in FIG. 1 is illustrated. For example, the exemplary graded matching layer structure 300 is configured for use in the transducer assembly 206 of FIG. 2.

In a presently contemplated configuration, the graded matching layer structure 300 is shown as including a support layer 302 having a first side and a second side, where the second side is opposite the first side. In one embodiment, the first side may include a top side and the second side may include a bottom side. As will be appreciated, the support layer 302 may be configured to provide mechanical support during the fabrication of the graded matching layer structure 300. Also, the support layer 302 may be formed using ceramic, a polymer, a metal, a composite, and the like. Moreover, the support layer 302 may be removed in the final transducer assembly.

As previously noted, the graded matching layer structure 300 is configured to effectively bridge the impedance differential between the low impedance patient 102 and a high impedance transducer element. To that end, the exemplary graded matching layer structure 300 may include a plurality of matching layers. By way of example, in the example of FIG. 3, the graded matching layer structure 300 is shown as including four matching layers. Reference numeral 304 is generally representative of a first matching layer, while reference numeral 306 is representative of a second matching layer. Similarly, a third matching layer is represented by reference numeral 308, while reference numeral 310 is representative of a fourth matching layer. It may be noted that in certain embodiments, the first matching layer 304 may be representative of a matching layer that is disposed in close proximity to the patient 102 during the imaging process, while the fourth matching layer may be representative of a matching layer that is coupled to the acoustic transducer array or elements. It may be noted that in accordance with exemplary aspects of the present technique, the various matching layers in the graded matching layer structure 300 may have substantially similar thicknesses or may have different thicknesses.

In accordance with aspects of the present technique, the graded matching layer structure may be formed by first forming a matching layer that is disposed adjacent to the acoustic transducer and working outward toward the body of the patient 102. Using the example of FIG. 3, the fourth matching layer 310 that is disposed in close proximity may be first formed on a substrate. Subsequently, the other matching layers such as the third matching layer 308 and the second matching layer 306 may be formed. The first matching layer 304 that is representative of a matching layer that is disposed in close proximity to the patient 102 during the imaging process may then be formed. Forming the graded matching layer structure as described hereinabove allows the more robust materials of the fourth matching layer 310, for example, to form a support for the lighter materials of the other matching layers 308, 306, 304 in the graded matching layer structure 300.

Furthermore, each of the matching layers in the graded matching layer structure 300 may be formed using a different material. By way of example, materials such as but not limited to ceramic, a polymer, metal, composites, or combinations thereof may be used to form the various matching layers. In one embodiment, the material used to form the matching layer may include a material slurry. Moreover, the material slurry may include a light curable particle filled material slurry, in certain embodiments. It may be noted that the light may include actinic radiation in the ultraviolet spectrum, the visible light spectrum, the infrared spectrum, the X-ray spectrum, or combinations thereof.

In addition, each of the matching layers has a different acoustic impedance. For example, the first matching layer 304 may have an acoustic impedance that is marginally greater than the acoustic impedance of the patient 102. Furthermore, the second matching layer 306 may have an acoustic impedance that is marginally greater than that of the first matching layer 304. In a similar fashion, the third matching layer 308 may have an acoustic impedance that is greater than the acoustic impedance of the second matching layer 306, while the fourth matching layer 310 may have an acoustic impedance that is greater than that of the third matching layer 306. However, it may be noted that the acoustic impedance of the fourth matching layer 310 may be lower than or equal to that of the high impedance transducer elements. By way of example, the acoustic impedance of the patient 102 may about 1.5 MRayls, while the acoustic impedance of an acoustic layer having the transducer elements may be in a range from about 10 MRayls to about 35 MRayls.

As described hereinabove, the graded matching layer structure 300 includes a plurality of matching layers. The matching layers may be formed using different materials. Additionally, the materials may have different values of the acoustic impedance. Moreover, each of the matching layers may have a different thickness. Consequently, an inhomogeneous graded matching layer structure 300 having a first side 312 and a second side 314 is provided. The inhomogeneous graded matching layer structure 300 aids in providing a gradual continuous change in acoustic impedance from the low impedance patient 102 to the high impedance transducer elements. It may be noted that the first side 312 of the graded matching layer structure 300 may be representative of a side of the graded matching layer structure 300 that is in contact with or disposed in close proximity to the patient 102. Also, an acoustic layer (not shown in FIG. 3) having one or more transducer elements (not shown in FIG. 3) may be operatively coupled to the second side 314 of the graded matching layer structure 300. In one embodiment, the support layer 302 may be removed to aid in positioning the first side 312 of the graded matching layer structure 300 in close proximity to the low impedance patient 102.

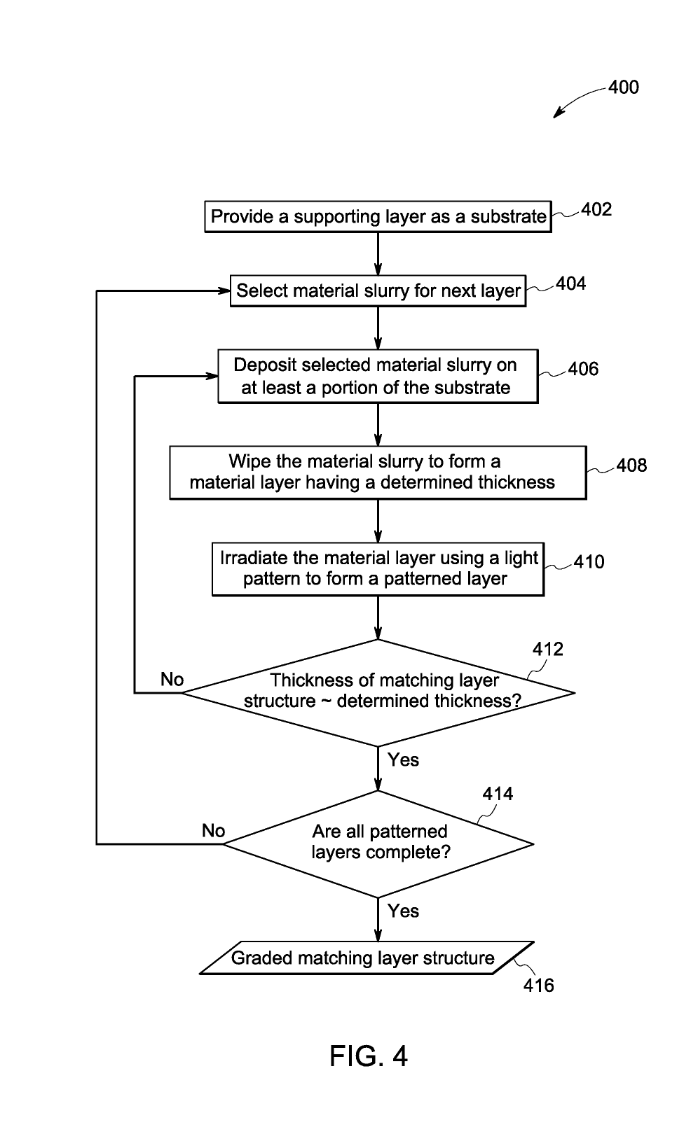

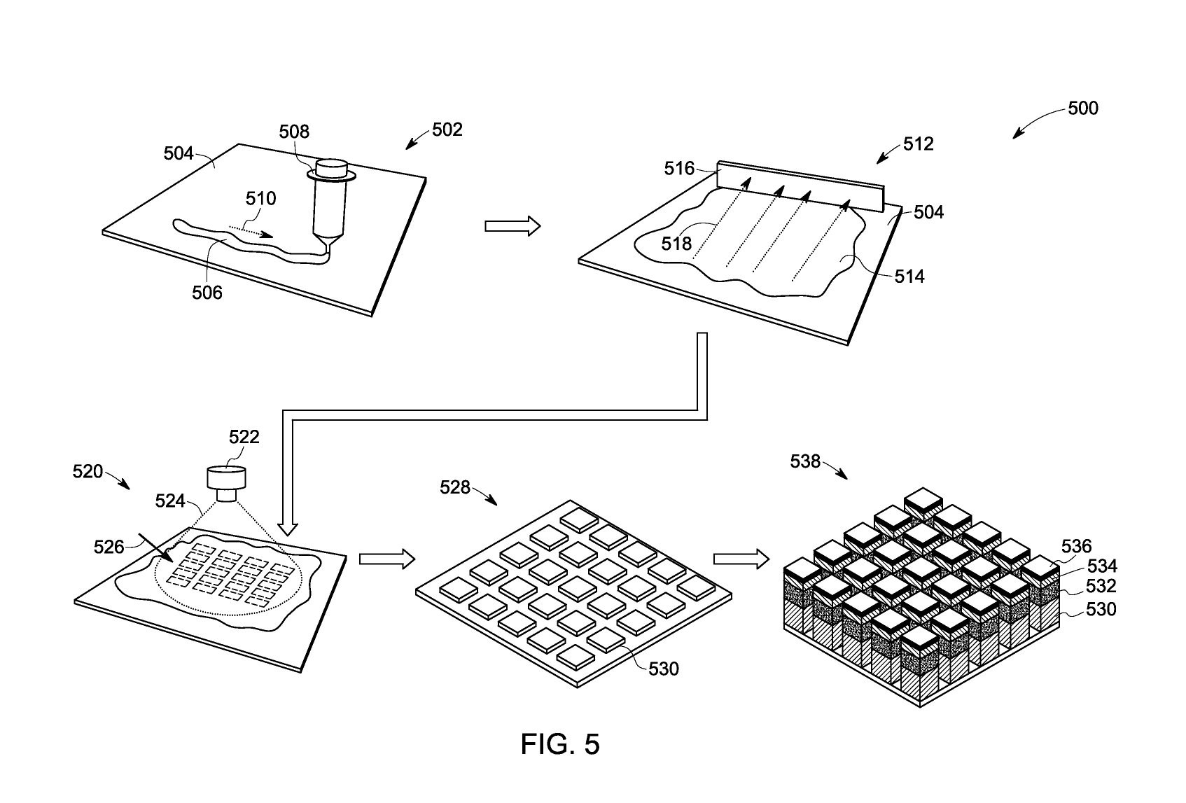

It may be noted that although the graded matching layer structure 300 of FIG. 3 is depicted as including four (4) matching layers for ease of illustration, use of other number of matching layers in the graded matching layer structure 300 is also envisaged. By way of example, the graded matching layer structure 300 may include more than five (5) matching layers, in one example. In accordance with aspects of the present technique, the true power of the graded matching layer structure 300 is realized when the number of matching layers in the graded matching layer structure 300 grows to a much larger number so that the difference in impedance between any adjacent matching layers are relatively “small”. An exemplary method for forming the graded matching layer structure 300 will be described in greater detail with reference to FIGS. 4-5.

As described hereinabove and depicted in FIG. 3, the entire matching layer structure includes the “graded” matching layer structure 300. Accordingly, the graded matching layer structure 300 is configured to fill the entire space between the first side 312 of the graded matching layer structure 300 that is in contact with the patient 102 and the second side 314 of the graded matching layer structure 300 that is operationally coupled to one or more transducer elements. However, in accordance with aspects of the present technique, the matching layer structure between the patient 102 and the transducer element may be formed using the graded matching layer structure 300 in conjunction with one or more other matching layers. Although not illustrated in FIG. 3, in one embodiment, the matching layer structure may include an arrangement of discrete quarter-wave matching layers or an arrangement of mass-spring based layers, or a combination thereof in combination with the graded matching layer structure 300. In one embodiment, another matching layer may be disposed between the graded matching layer structure 300 and the patient 102, where the graded matching layer structure 300 is operationally coupled to the transducer element. In another embodiment, another matching layer may be disposed between the graded matching layer structure 300 and the transducer element, where the graded matching layer structure 300 is disposed adjacent to the patient 102. Additionally, in yet another embodiment, the graded matching layer structure 300 may be sandwiched between at least a first matching layer and a second matching layer. By forming the matching layer structure as described hereinabove, a plurality of impedance matching strategies may be used in combination to enhance the resolution of the imaging system and/or the penetration of the beam energy.

FIG. 4 is a flow chart 400 depicting an exemplary method for forming a graded matching layer structure. In particular, a method for forming the graded matching layer structure 300 of FIG. 3 is presented. The method starts at step 402 where a support layer having a first side and a second side is selected. The support layer may include a platen, for example. Also, the support layer may include one of a plastic, a metal, a ceramic, silicon, a polymer or glass. It may be noted that the support layer may be configured as a substrate to provide mechanical strength to the graded matching layer structure during the fabrication process.

Moreover, at step 404, a material slurry may be selected to form for a next layer in a graded matching layer structure. Accordingly, at step 406, the selected material slurry may be disposed on at least a portion of the support layer. It may be noted that the terms support layer and substrate may be used interchangeably. The material slurry may include a polymer or a ceramic paste, in one example. Also, the material slurries may include light curable particle filled material slurries. As previously noted, the light may include actinic radiation in the ultraviolet spectrum, the visible light spectrum, the infrared spectrum, the X-ray spectrum, or combinations thereof. Moreover; the material slurries may also include monomers that may be polymerized with actinic radiation.

In one example, a material slurry dispenser may be employed to dispense the material slurry on the portion of the support layer. The material slurry may be dispensed through an air-powered dispenser, a mechanically driven dispenser, and the like, or combinations thereof.

Once the material slurry is deposited on the support layer, the material slurry may be spread to form a material layer, as depicted by step 408. Particularly, the material slurry may be smoothed such that the material layer having a determined uniform thickness is formed. In one example, a smoothing device and/or smoothing processes such as thick film layering techniques may be used to smooth the material slurry. By way of example, the smoothing device may include a wiping or doctoring blade. Also, the smoothing processes may include doctor blading, spin coating, dip coating, spraying, tape coating, screen printing, thermal spraying, or combinations thereof.

Moreover, in accordance with aspects of the present technique, at step 410, the material layer may be irradiated or exposed to light to pattern the material layer. In one embodiment, the light may include actinic radiation in the ultraviolet spectrum, the visible light spectrum, the infrared spectrum, the X-ray spectrum, or combinations thereof. It may be noted that actinic radiation may include electromagnetic radiation that can produce photochemical reactions, in one example. In accordance with aspects of the present technique, a digital light projector may be employed as a light source. Furthermore, a desired light pattern to configure the material layer may be generated. As used herein, the term desired light pattern may generally be representative of an arrangement used to pattern the material layer. The arrangement may generally be representative of a geometric pattern that is generally representative of a desired transducer structure. By way of example, the desirable transducer structure may include a shape of a transducer element, pillars for a composite structure, and the like. Accordingly, a digital light pattern mask may be generated based on the desired pattern. Subsequently, the first material layer may be exposed to the light from the light source. In particular, the material slurry may be exposed to the light that is passed through the digitally generated light pattern mask to pattern the material layer. Following the exposure to the light that has been passed through the digitally generated light mask, a portion of the material layer that is exposed to the light may be cured and therefore be hardened. However, a portion of the material layer that is shielded from the light may be left uncured. Consequent to the patterning of the material layer at step 410, a patterned matching layer is formed.

In accordance with other aspects of the present technique, a glass plate based pattern mask may be employed to pattern the material layers. For example, a glass plate having a metal mask disposed on at least one side may be employed. In particular, the glass plate based pattern mask may be generated based on the desired pattern. The first material layer may be exposed to the light from the light source that is passed through the glass plate based pattern mask to pattern the material layer. Consequent to the exposure to the light that has been passed through the glass plate based pattern mask, a portion of the material layer that is exposed to the light may be cured and therefore be hardened to form a patterned matching layer.

Once the material layer is patterned to form the matching layer, a measurement may be carried out to verify if the thickness of the matching layer is less than a determined threshold thickness, as indicated by step 412. The threshold thickness may representative of a desired thickness of the matching layer. At step 412, if it is determined that the thickness of the matching layer is less than the determined thickness, then more material slurry may be deposited on the matching layer and steps 406-412 may be repeated until the thickness of the matching layer is substantially equal to the determined thickness.

Subsequently, at step 414, a check may be carried out to verify if a desired number of patterned matching layers have been formed. By way of example, if it is desirable to form a graded matching layer structure with four (4) matching layers, then at step 414 a check may be carried out to verify if all the four patterned matching layers have been formed. At step 414, if it is determined that the desired number of patterned layers has not been formed, then steps 404-414 may be repeated to form one or more additional matching layers until the graded matching layer structure having the desired number of patterned matching layers is formed. For example, another material slurry may be selected to form a next matching layer and the process of steps 404-414 may be repeated. As previously noted, the various patterned matching layers in the graded matching layer structure may all have a substantially similar thickness or different thicknesses. However, at step 414, if it is determined that the desired number of patterned layers has been formed, the layered structure may be further processed.

It may be noted that in accordance with exemplary aspects of the present technique, each matching layer in the graded matching layer structure may include a different material. Also, each of the matching layers may be formed using a material having a different acoustic impedance. Specifically, the materials used to form the different matching layers may be selected such that their acoustic impedances provide a continuous uniform/gradual change from the low acoustic impedance patient to the high acoustic impedance transducer. For example, the first matching layer may be representative of a matching layer in the graded matching layer structure that is disposed adjacent to the patient for imaging. Also, the first matching layer may be formed using the first material slurry that has a first acoustic impedance value employing steps 404-412. The first acoustic impedance value may have an impedance value that is marginally higher than or equal to the low impedance value of the patient. Consequently, there is a gradual change/transition of impedance between the low impedance patient and the first matching layer.

Subsequently, a second material slurry may be selected and deposited on the first matching layer (see steps 404-406). It may be noted that the second material slurry may be selected such that an acoustic impedance of the second material slurry is once again marginally greater than the acoustic impedance of the first matching layer. Selecting the second material slurry as noted hereinabove aids in providing a continuous gradual change in impedance values across the matching layers in the graded matching layer structure. Furthermore, in one embodiment, the first material dispenser may be washed and reused to deposit the second material slurry on the first matching layer. However, in certain other embodiments, more than one material slurry dispenser may be employed to dispense a respective material slurry.

Following the deposition of the second material slurry over the first matching layer, a smoothing device such as a wiping blade may be employed to smoothen the second material slurry to form a second material layer having a uniform thickness (see step 408). It may be noted that in one embodiment, the second material layer may have a thickness that is substantially similar to the thickness of the first material layer. However, in certain other embodiments, the two material layers may have different corresponding thicknesses. Particularly, the thickness of each matching layer may be dependent on a corresponding acoustic velocity of the material used to form that matching layer.

Here again, the second material layer may be exposed to light to pattern the second material layer. In particular, a digitally generated light mask may be employed to pattern the second material layer to form a second matching layer (see step 410). Additionally, a check may be carried out to verify if the second matching layer has a desired thickness. However, if the desired thickness is not achieved, then the process of steps (406)-(414) may be repeated till a second matching layer of the desired thickness is formed. Additionally, if the second matching layer of desired thickness if formed, then a check may be carried out to verify if a desired number of patterned matching layers is formed (see step 414). At 414, if it is determined that the desired number of patterned matching layers have not been formed, then steps 404-414 may be repeated until a layered structure having the desired number of patterned matching layers is formed.

If the layered structure having the desired number of patterned matching layers is formed, the cured material layers may be prepared for thermal treatment. In one embodiment, as an intermediate step, any uncured material slurries may be at least partially removed. For example, the uncured material may be removed by employing ultrasonic rinsing using 2, propanol generally found in an ultrasonic cleaner. Subsequently, the matching layers in layered structure may be thermally treated to solidify and form a graded matching layer structure 416. As previously noted, the graded matching layer structure 416 is an inhomogeneous matching layer structure as different materials are used to form the structure.

The graded matching layer structure 416 so formed substantially improves the penetration or sensitivity and resolution of an ultrasound transducer. Also, the various matching layers in the graded matching layer structure provide a gradual change in acoustic impedance to match the impedance differential between the low impedance patient and the high impedance transducer. In one embodiment, the gradual change in acoustic impedance may include a stepwise monotonic change in acoustic impedance. Furthermore, the exemplary method permits fabrication on patterned matching layer structures. Moreover, composite transducer structures typically include stiff particles or pillars in a softer matrix. Particularly, in the case of pillars, acoustic waves travel preferentially along the pillars and are attenuated by the softer matrix. Accordingly, composite structures may be employed to minimize lateral mode response and to improve the sensitivity of the ultrasound transducer. Additionally, because these steps are all easily controlled by electromechanical elements, the method also offers the possibility of faster, touch-free roll-to-roll processing of ultrasound transducers.

As described hereinabove and depicted in FIG. 4, the entire matching layer structure includes the “graded” matching layer structure 416. However, in accordance with aspects of the present technique, the matching layer structure may be formed by using one or more matching layers in addition to the graded matching layer structure 416 to form a matching layer structure. By way of example, the other matching layer may include an arrangement of discrete quarter-wave matching layers, an arrangement of mass-spring based layers, or a combination thereof. In one example, another matching layer may be disposed between the graded matching layer structure 416 and the patient 102, where the graded matching layer structure 416 is operationally coupled to the transducer element. Moreover, in another example, another matching layer may be disposed between the graded matching layer structure 300 and the transducer element, where the graded matching layer structure 416 is disposed adjacent to the patient 102. Furthermore, in yet another example, the graded matching layer structure 416 may be sandwiched between at least a first matching layer and a second matching layer. The matching layer structure thus formed may include a plurality of impedance matching strategies which may be used in combination to enhance the resolution of the imaging system and/or the penetration of the beam energy.

Turning now to FIG. 5, progressive structures are illustrated, made in an exemplary process 500 of fabricating an exemplary graded matching layer structure, such as the graded matching layer structure 300 shown in FIG. 3, in accordance with aspects of the present technique. As previously noted, the graded matching layer structure may include two or more matching layers disposed on a first side of the acoustic layer.

The process begins at step 502 where a substrate or support layer 504 is provided. The support layer 504 may include a platen in certain embodiments. Also, the support layer 504 may be formed using ceramic, a polymer, a metal and the like. The support layer 504 may be used as a base while forming a graded matching layer structure.

Subsequently, a first material slurry 506 may be deposited on the support layer 504. In certain embodiments, a material slurry dispenser 508 may be used to deposit the first material slurry 506 on the support layer 504. As previously noted, the first material slurry 506 may be a polymer or a ceramic paste. Also, the first material slurry 506 is selected such that an acoustic impedance of the first material slurry 506 is marginally greater than the acoustic impedance of the low impedance patient. Reference numeral 510 is generally representative of a direction of movement of the material slurry dispenser 508 to dispense the first material slurry 506.

Once the first material slurry 506 has been deposited on the support layer 504, it is desirable to form a first material layer having a uniform thickness. Accordingly, at step 512, the first material slurry 506 may be spread to form a first material layer 514 having a uniform layer thickness. In one embodiment, a smoothing device 516 may be used to spread or smoothen the first material slurry 506. The smoothing device 516 may include a wiping blade, in certain examples. Reference numeral 518 is generally representative of a direction of movement of the smoothing device 516 as the first material slurry 506 is smoothen to form the first material layer 514.

Following the formation of the first material layer 514, the first material layer 514 may be irradiated with light that is passed through a digitally generated light pattern mask to pattern the first material layer 514, as depicted by step 520. Patterning the first material layer 514 facilitates formation of a first matching layer 514 in a graded matching layer structure. To that end, a digital light source 522 may be employed to provide light 524. In accordance with exemplary aspects of the present technique, a digitally generated light pattern mask 526 may be generated. This light pattern mask 526 is generally representative of a desired pattern for patterning the first material layer 514. Accordingly, the first material layer 514 may be exposed to the light 524 that passes through the digitally generated light mask 526 to pattern the first material layer. Subsequent to this exposure, a first matching layer 530 may be formed, as depicted by step 528.

As previously noted, if the thickness of the first matching layer 530 is less than a desired threshold thickness, then a second material slurry may be deposited over the patterned first matching layer 530. Also, steps 502, 512 and 520 may be repeated to form a patterned second matching layer 532. Moreover, as previously noted, the second material slurry is selected such that an acoustic impedance of the second material slurry is marginally greater than that of the first material slurry thereby providing a gradual uniform transition of impedance between the matching layers 530, 532.

Once it is determined that the thickness of the plurality of matching layers is greater than the desired threshold thickness, then the cured matching layers 530, 532 are readied for thermal treatment or the like. To that end, any uncured material slurries in the matching layers 530, 532 may be removed. Moreover, as previously noted, as an intermediate step, any uncured material slurries may be removed by employing ultrasonic rinsing using 2, propanol generally found in an ultrasonic cleaner. Subsequently, the matching layers in material layer structure may be thermally treated to solidify and form a graded matching layer structure 538. It may be noted that in certain embodiments, the support layer 504 may be removed to from the graded matching layer structure 538. In FIG. 5, the graded matching layer structure 538 is shown as include four matching layers 530, 532, 534, 536. However, it may be noted that the graded matching layer structure 538 may include more than four matching layers.

In accordance with further aspects of the present technique, the graded matching layer structure 538 may be operatively coupled to an acoustic layer to form an acoustic stack for use in a transducer assembly. It may be noted that the acoustic layer may include one or more transducer elements. In certain embodiments, the acoustic stack may also be operatively coupled to an interconnect layer. The methods of electrically coupling the transducer assembly to the interconnect layer and/or a substrate may include lamination with electrically conductive or non-conductive epoxy, for example.

The graded matching layer structure 538 having the four matching layers 530, 532, 534, 536 may be configured to facilitate the matching of an impedance differential that may exist between the high impedance transducer elements and the low impedance patient 102 (see FIG. 1). By way of example, the first matching layer 530 may be representative of a matching layer in the graded matching layer structure 538 that is disposed adjacent to the low impedance patient 102 for imaging a region of interest in the patient 102. Also, the fourth matching layer 536 may be representative of a matching layer in the graded matching layer structure 538 that is disposed adjacent to the high impedance transducer. Accordingly, the four matching layers 530, 532, 534, 536 in the graded matching layer structure 538 provide a gradual change in impedance to match the impedance differential between the low impedance patient 102 and the high impedance transducer. In one embodiment, the gradual change in impedance may include a stepwise, monotonic change in impedance.

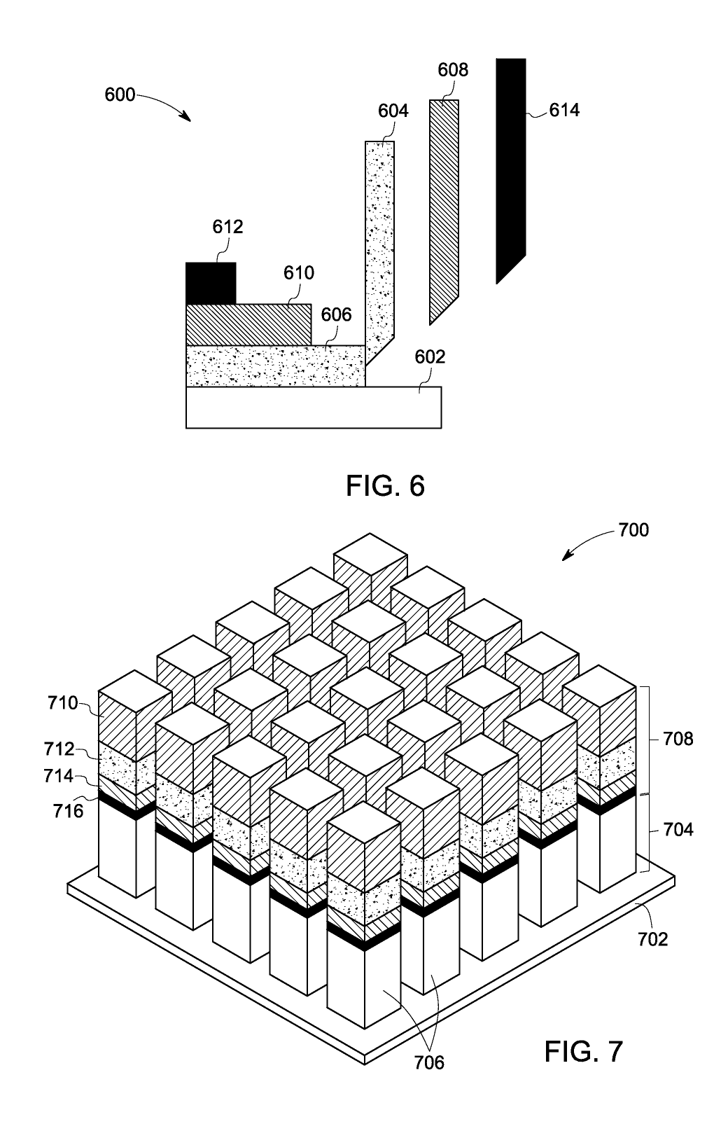

FIG. 6 depicts a diagrammatical illustration 600 of the use of multiple material slurry dispensers for forming a graded matching layer structure, such as the graded matching layer structure 300 of FIG. 3. As previously noted, the material slurry dispensers may include air-powered dispensers, mechanically driven dispensers, or a combination thereof. Particularly, in this embodiment, a plurality of material slurry dispensers is employed to dispense the various material slurries. Reference numeral 602 is generally representative of a support layer, such as the support layer 504 of FIG. 5. Also, reference numeral 604 is generally representative of a first material slurry dispenser that is configured to deposit a first material slurry 606 on the support layer 602. Also, a second material slurry dispenser 608 may be employed to deposit a second material slurry 610 on a first matching layer that has been patterned as described with reference to FIGS. 4-5. In a similar fashion, a third material slurry 612 may be deposited on a patterned second, matching layer using a third material slurry dispenser 614.

Referring now to FIG. 7, a diagrammatical representation 700 of a perspective view of a transducer assembly including an exemplary graded matching layer structure, such as graded matching layer structure 534 (see FIG. 5) is depicted. As depicted in FIG. 7, a substrate 702 may be selected. The substrate 702 may include one of a plastic, a metal, a ceramic, silicon, a polymer or glass. It may be noted that the substrate 702 may be configured to provide mechanical strength to the transducer assembly 700 during the fabrication process.

Subsequently, an acoustic layer 704 may be patterned on a first side of the substrate 702. It may be appreciated that the acoustic layer 704 may be representative of one or more transducer elements arranged in a determined pattern. Furthermore, in certain other embodiments, the acoustic layer 704 may also be applied as a uniform layer and isolated only after the rest of the graded matching layer structure is complete. In one example, the acoustic layer 704 may include transducer elements 706 that are arranged in a spaced relationship, such as, but not limited to, an array of transducer elements disposed on a layer, where each of the transducer elements 706 may include a transducer front face and a transducer rear face (not shown in FIG. 7). As will be appreciated by one skilled in the art, the transducer elements may be fabricated employing materials, such as, but not limited to lead zirconate titanate (PZT), PMNT, composite PZT, or micromachined silicon.

As will be appreciated, the acoustic layer 704 may be configured to generate and transmit acoustic energy into the patient 102 (see FIG. 1) and receive backscattered acoustic signals from the patient 102 to create and display an image. In addition, the acoustic layer 704 may include a plurality of transducer elements. Furthermore, the acoustic layer 704 may include lead zirconate titanate (PZT), PMNT, a piezoelectric ceramic, a piezocomposite, a piezoelectric single crystal, or a piezopolymer. It may be noted that in certain embodiments, the acoustic layer 704 may include multiple layers of the aforementioned materials. More particularly, in one embodiment, the acoustic layer 704 may include multiple layers of the same material, while in another embodiment, the acoustic layer 704 may include multiple layers of different materials. Also, the acoustic layer 704 may have a thickness in a range from about 50 microns to about 600 microns. In one embodiment, the acoustic layer 704 may have a thickness of about 65 microns.

Subsequently, a graded matching layer structure 708 may be disposed on a first side of the acoustic layer 704. The graded matching layer structure 708 may then be operatively coupled to the acoustic layer 704 to form the transducer assembly 700. In the example depicted in FIG. 7, the graded matching layer structure 708 is shown as including four matching layers. However, fewer or more than four matching layers may be used to form the graded matching layer structure 708.

In the example of FIG. 7, reference numeral 710 is representative of a first matching layer, while a second matching layer is indicated by reference numeral 712. Moreover, a third matching layer and a fourth matching layer in the graded matching layer structure 708 are represented by reference numerals 714 and 716 respectively. In this example, the first matching layer 710 may be representative of a matching layer that is disposed adjacent to the patient 102 for imaging, while the fourth matching layer 716 may be representative of a matching layer that is disposed adjacent to the high impedance transducer elements 706. It may be noted that in accordance with further aspects of the present technique, the graded matching layer structure 708 may be directly formed on the acoustic layer 704 to form the transducer assembly 700.

As previously noted, in accordance with exemplary aspects of the present technique, the graded matching layer structure 708 is formed such that that various layers in the graded matching layer structure 708 provide a controlled continuous change in acoustic impedance as a function of structure. For example, the graded matching layer structure 706 is formed such that the matching layers 710, 712, 714, 716 provide a continuous gradual change in acoustic impedance across the graded matching layer structure 708, thereby bridging the differential in acoustic impedance that may exist between the low impedance patient 102 and the high impedance transducer elements 706.

In certain embodiments, a lens (not shown in FIG. 7) may be disposed adjacent to a front face of the graded matching layer structure 708 and configured to provide an interface between the patient 102 and the graded matching layer structure 708. Additionally, in certain embodiments, the lens may be configured to facilitate focusing of the ultrasound beam. Alternatively, the lens may include a non-focusing layer.

In addition, the transducer assembly 700 may include a backing structure (not shown in FIG. 7), having a front face and a rear face, which may be fabricated employing a suitable acoustic damping material possessing high acoustic losses. The backing structure may be acoustically coupled to the rear face of the array of transducer elements 706, where the backing structure facilitates the attenuation of acoustic energy that may emerge from the rear face of the array of transducer elements 706.

Moreover, the transducer assembly 700 may also include an electrical shield (not shown in FIG. 7) that facilitates the isolation of the transducer elements from the external environment. The electrical shield may include metal foils, where the metal foils may be fabricated employing metals such as, but not limited to, copper, aluminum, brass, and gold.

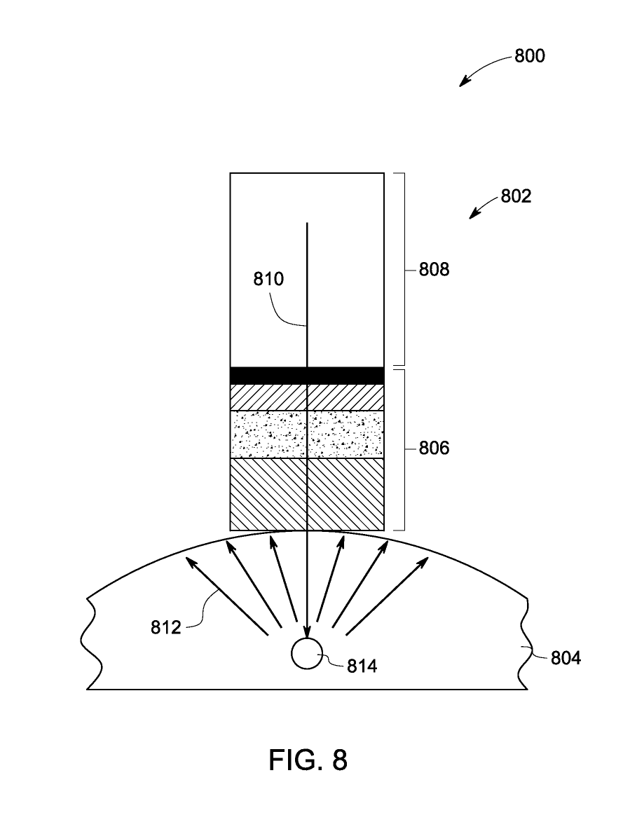

FIG. 8 is a diagrammatic illustration 800 of use of a transducer assembly 802, such as the transducer assembly 700 (see FIG. 7) for imaging an object of interest 804. In particular, the transducer assembly 802 includes an exemplary graded matching layer structure 806 such as the graded matching layer structure 706 of FIG. 7 that is operationally coupled to an acoustic layer 808. Moreover, the acoustic layer 808 may include a plurality of transducer elements. As previously noted, the object of interest may include a patient, such as the patient 102 of FIG. 1. The graded matching layer structure 806 may be placed in direct contact or in close proximity with a body 804 of the patient 102 for imaging an anatomical region of interest. This exemplary graded matching layer structure 806 aids is matching an impedance differential that may exist between the body 806 of the low impedance patient 102 and high impedance acoustic transducer elements 808, such as the acoustic transducer elements 706 (see FIG. 7). Reference numeral 810 is generally representative of acoustic energy impinging on the body 804 of the patient 102, while reference numeral 812 is generally representative of acoustic energy reflected isotropically from a region 814 in the body 804 of the patient 102.

By employing the method of forming the graded matching layer structure as described hereinabove, a transducer assembly with enhanced resolution and improved sensitivity may be obtained. Also, the transducer assembly thus formed may then be disposed in an ultrasonic probe. Accordingly, an ultrasound probe having the transducer assembly with a broad fractional bandwidth greatly enhances quality of imaging, resolution of the imaging system, and clinical workflow.

The graded matching layer structure and method for forming the graded matching layer structure described hereinabove provides a method to directly deposit and pattern a graded matching layer structure on ultrasound transducers. The graded matching layer structure can improve the penetration or sensitivity and resolution of an ultrasound transducer. The present method permits the fabrication on patterned matching layer structures, a key architecture that can be used with engineered (aperiodic) composite structures to minimize lateral mode response and to improve their sensitivity. Moreover, the method also offers the possibility of faster, touch-free roll-to-roll processing of ultrasound transducers. In addition, the present method uses light to pattern various materials to form the matching layers in the graded matching layer structure.

While only certain features of the disclosure have been illustrated and described herein, many modifications and changes will occur to those skilled in the art. It is, therefore, to be understood that the appended claims are intended to cover all such modifications and changes as fall within the true spirit of the disclosure.

1. A method for forming a graded matching layer structure, the method comprising:
a. depositing a first material slurry on at least a portion of a substrate;
b. spreading the first material slurry to a form a first material layer having a first determined thickness;
c. exposing the first material layer using light processed through a determined light pattern mask to form a first matching layer;
d. repeating steps (a)-(c) with different material slurries to form the graded matching layer structure.

2. The method of claim 1, wherein the light comprises actinic radiation in the ultraviolet spectrum, the visible light spectrum, the infrared spectrum, the X-ray spectrum, or combinations thereof.

3. The method of claim 1, wherein the material slurries comprise a ceramic paste, a metal paste, an oxide paste, a polymer paste, or combinations thereof.

4. The method of claim 1, wherein the material slurries comprise monomers polymerizable with actinic radiation.

5. The method of claim 1, wherein the different material slurries comprise light curable particle filled material slurries.

6. The method of claim 1, wherein the material slurries are dispensed through an air-powered dispenser, a mechanically driven dispenser, or a combination thereof.

7. The method of claim 1, wherein spreading the first material slurry to form the first layer comprises smoothing the first material slurry.

8. The method of claim 7, wherein smoothing the first material slurry comprises doctor blading, spin coating, screen printing, tape coating, spraying, dip coating, or combinations thereof.

9. The method of claim 1, further comprising generating the determined light pattern mask based on a desired pattern of the first matching layer.

10. The method of claim 1, wherein the determined light pattern mask comprises a digitally generated light pattern mask, a glass plate based mask, or a combination thereof.

11. The method of claim 1, wherein exposing the first material layer to form the first matching layer further comprises depositing the first material slurry on the first matching layer to form the first matching layer of a desired thickness.

12. The method of claim 1, wherein exposing the first material layer using the light processed through the determined light pattern mask comprises curing the first material slurry of the first material layer to form a cured first matching layer.

13. The method of claim 1, further comprising:
at least partially removing uncured material slurry; and
thermally treating the cured matching layer.

14. The method of claim 1, wherein steps (a)-(c) are repeated with the different material slurries to form the graded matching layer structure having a desired number of matching layers.

15. The method of claim 1, further comprising employing a different material slurry dispenser to dispense each of the different material slurries.

16. The method of claim 1, further comprising operatively coupling the graded matching layer structure to an acoustic layer to form a transducer assembly.

17. The method of claim 16, wherein operatively coupling the graded matching layer structure to an acoustic layer comprises directly forming the graded matching layer structure on the acoustic layer.

18. The method of claim 1, further comprising disposing an arrangement of discrete quarter-wave matching layers, an arrangement of mass-spring based layers, or a combination thereof.

19. A graded matching layer structure, comprising:
a plurality of matching layers arranged in a stacked structure, wherein each matching layer in the stacked structure has a different acoustic impedance, and wherein the stacked structure is configured to provide a stepwise monotonic change in acoustic impedance across the stacked structure.

20. The graded matching layer structure of claim 19, further comprising a substrate configured to support the graded matching layer structure.

21. The graded matching layer structure of claim 19, further comprising an acoustic layer having one or more transducer elements operatively coupled to one side of the graded matching layer structure.

22. The graded matching layer structure of claim 19, wherein a shape of the graded matching layer structure comprises a square, a rectangle, an octagon, a circle, a rhombus, a triangle or combinations thereof.

23. The graded matching layer structure of claim 19, further comprising an arrangement of discrete quarter-wave matching layers, an arrangement of mass-spring based layers, or a combination thereof.

24. A transducer assembly, comprising:
a transducer array comprising one or more transducer elements disposed in determined pattern; and
a graded matching layer structure operatively coupled to the transducer array and comprising a plurality of matching layers arranged in a stacked structure, wherein each matching layer in the stacked structure has a different acoustic impedance, and wherein the stacked structure is configured to provide a monotonic change in acoustic impedance across the stacked structure.

25. The assembly of claim 24, wherein the transducer array comprises a piezoelectric array, a micromachined ultrasound array, or a combination thereof.

26. The assembly of claim 25, wherein the piezoelectric array comprises a lead zirconate titanate array, a lead magnesium niobate lead titanate array, or a combination thereof.

27. A system, comprising:
an acquisition subsystem configured to acquire image data, wherein the acquisition subsystem comprises a probe configured to image a region of interest, wherein the probe comprises at least one transducer assembly, wherein the at least one transducer assembly comprises a graded matching layer structure and a transducer array, wherein the graded matching layer structure comprises a plurality of matching layers arranged in a stacked structure, wherein each matching layer in the stacked structure has a different acoustic impedance, and wherein the stacked structure is configured to provide a stepwise monotonic change in acoustic impedance across the stacked structure; and
a processing subsystem in operative association with the acquisition subsystem and configured to process the image data acquired via the acquisition subsystem.

28. The system of claim 27, wherein the processing subsystem comprises an imaging system, wherein the imaging system comprises an ultrasound imaging system, a magnetic resonance imaging system, an X-ray imaging system, a nuclear imaging system, a positron emission tomography system, or combinations thereof.
